(19) United States
(12) Patent Application Publication
(10) Pub. No.: US 2013/0248822 A1
(43) Pub. Date: Sep. 26, 2013

(54) Broadband Polymer Photodetectors Using Zinc Oxide Nanowire as an Electron-Transporting Layer

(71) Applicant: XIONG GONG, Hudson, OH (US)

(72) Inventor: XIONG GONG, Hudson, OH (US)

(21) Appl. No.: 13/849,948

(22) Filed: Mar. 25, 2013

Related U.S. Application Data
(60) Provisional application No. 61/614,684, filed on Mar. 23, 2012.

(51) Int. Cl. H01L 51/42

(52) U.S. Cl. CPC H01L 51/4266
USPC 257/26; 438/82

(57) ABSTRACT

A polymer photodetector has an inverted device structure that includes an indium-tin-oxide (ITO) cathode that is separated from an anode by an active layer. The active layer is formed as a composite of conjugated polymers, such as PDDTT and PCBM. IN addition, a cathode buffer layer formed as an matrix of ZnO nanowires is disposed upon the ITO cathode, while a MoO₃ anode buffer layer is disposed between a high work-function metal anode and the active layer. During operation of the photodetector, the ZnO nanowires allows the effective extraction of electrons and the effective blocking of holes from the active layer to the cathode. Thus, allowing the polymer photodetector to achieve a spectral response and detectivity that is similar to that of inorganic photodetectors.

### CROSS-REFERENCE TO RELATED APPLICATION

This application claims the benefit of U.S. Provisional Application No. 61/614,684 filed on Mar. 23, 2012, the contents of which are incorporated herein by reference.

### TECHNICAL FIELD

Generally, the present invention relates to polymer photodetectors. In particular, the present invention relates to high-performance broadband polymer photodetectors having an inverted structure with an indium-tin-oxide (ITO) cathode and a high work-function metal anode. More particularly, the present invention relates to high-performance broadband polymer photodetectors having an inverted structure with an active layer formed of a conjugated polymer and a cathode buffer layer formed of a matrix of zinc oxide nanowires.

### BACKGROUND ART

Over the last several decades, polymer electronic and optoelectronic devices, such as field effect transistors (FET), light emitting diodes (LED), solar cells, photodetectors (PD), and the like have been extensively investigated due to their potential of being fabricated on flexible, lightweight substrates using low-cost, high-volume printing techniques. Specifically, polymer photodetectors (PD) have gained a substantial amount of attention from industries for use in various applications, due to their low-cost processing and high-performance operation. Moreover, with the development of new low or narrow bandgap conjugated polymers and through refined control over the nanoscale morphology of the interpenetrating electron donor/acceptor networks, increased detectivity performance has been achieved, whereby such solution-processed polymer photodetectors are now capable of attaining a spectral response that ranges from the ultraviolet (UV) region to the infrared (IR) region. Furthermore, photodetectors that utilize low bandgap conjugated polymers exhibit photoresponsitivity from the ultraviolet (UV) region to the near infrared (NIR) region with the detectivity over 10¹³ Jones (1 Jones=1 cmHz^{1/2}/W), have led to a potential substitute for inorganic counterparts.

Currently, polymer photodetectors are fabricated using a typical device architecture, in which a bulk heterojunction (BHJ) composite of semiconducting polymers, as the electron donors, and fullerene derivatives, as the electron acceptors, is sandwiched between a poly(3,4-ethylenedioxythiophene):poly(styrenesuflonate) (PEDOT:PSS) modified indium tin oxide (ITO) anode and a low work-function metal cathode, such as aluminum (Al). That is, similar to polymer solar cells (PSC), polymer photodetectors (PD) are typically fabricated with a transparent conductive anode, such as indium tin oxide (ITO); a low work-function metal cathode, such as aluminum, calcium, barium; and an active layer, comprising a mixture of polymer and fullerene derivatives that are sandwiched between the anode and cathode. While poly(3,4-ethylendioxythiophene):poly(styrene sulfonate), or PEDOT:PSS, is often used as an anode buffer layer, the acidity of PEDOT:PSS causes the ITO to become unstable, thereby contaminating the PEDOT:PSS polymer, and thus degrading the performance of the devices formed by such process. Furthermore, because the cathodes of such devices are primarily air-sensitive metals that are susceptible to degradation, and because the aluminum used to form such cathodes is inherently flawed, such photodetector devices formed of such materials do not achieve a stable, long-term operating life.

Therefore, there is a need for a polymer photodetector having an inverted structure, whereby the direction of electron charge collection is reversed, such that an ITO layer forms a cathode (bottom), and a high work-function metal improves the stability of the device forms an anode (top). In addition, there is a need for a polymer photodetector that has improved stability that can be fabricated using a simplified solution-process based manufacturing process, and at reduced cost. In addition, there is a need for a polymer photodetector that uses a narrow bandgap conjugated polymer as an active layer. Still yet there is a need for a polymer photodetector that uses a cathode buffer layer of a matrix of ZnO nanowires to provide increased sensitivity and broadband spectral frequency response thereto. In addition, there is a need for a photodetector device that does not utilize a PEDOT:PSS active layer, so as to increase the long-term stability of the device. There is also a need for a polymer photodetector device that is formed using a coating or printing technique, such as roll-to-roll processing that simplifies and lowers the manufacturing costs of such devices.

### SUMMARY OF THE INVENTION

In light of the foregoing, it is a first aspect of the present invention to provide polymer photodetector having an inverted structure that includes an at least partially light transparent cathode; a metal anode; a first buffer layer disposed upon said cathode, said first buffer layer including a matrix of ZnO nanowires; an active layer disposed upon said first buffer layer, said active layer comprising one or more conjugated polymers and a fullerene; and a second buffer layer disposed between said active layer and said metal anode.

In another aspect of the present invention a polymer photodetector having an inverted structure includes an at least partially light transparent cathode; a metal anode; a first buffer layer disposed upon said cathode, said first buffer layer including a matrix of n-type metal oxide nanowires; an active layer disposed upon said first buffer layer, said active layer including one or more conjugated polymers as an electron donor, and one or more organic molecules as an electron acceptor; and a second buffer layer disposed between said active layer and said metal anode, said second buffer layer comprising a metal complex.

In yet another aspect of the present invention provides a method of forming a photodetector having an inverted structure that comprises providing an at least partially light transparent cathode; disposing a first buffer layer upon said at least partially light transparent cathode, said first buffer layer including a matrix of n-type metal oxide nanowires; disposing an active layer upon said first buffer layer, said active layer including one or more conjugated polymers as an electron donor, and one or more organic molecules as an electron acceptor; disposing a second buffer layer upon said active layer, said second buffer layer comprising a metal complex; and disposing a metal anode upon said second buffer layer.

### BRIEF DESCRIPTION OF THE DRAWINGS

These and other features and advantages of the present invention will become better understood with regard to the following description, appended claims, and accompanying drawings wherein:

FIG. 1 is a diagrammatic view of a polymer photodetector (PD) in accordance with the concepts of the present invention;

FIG. 2 is a diagrammatic view of an SEM (scanning electron microscope) image of the ZnO nanowires that form a cathode buffer layer of the polymer photodetector in accordance with the concepts of the present invention;

FIG. 3 is a diagrammatic view of the molecular structures of PDDTT and PCBM combined as a composite material to form an active layer of the polymer photodetector in accordance with the concepts of the present invention;

FIG. 4 is a diagrammatic view of the energy bands associated with the various layers forming the polymer photodetector in accordance with the concepts of the present invention;

FIG. 5 is a graph showing the J-V characteristics of the polymer photodetector under AM1.5G illumination from a calibrated solar simulator with light intensity of 100 mW/cm², 800 nm light with an intensity of 0.22 mW/cm², and in the dark, in accordance with the concepts of the present invention;

FIG. 6 is a graph showing the absorption spectrum of PDDTT and PCBM polymer thin films of the active layer and the external quantum efficiency (EQE) of the polymer photodetector under zero bias in accordance with the concepts of the present invention; and

FIG. 7 is a graph showing the detectivity of the polymer photodetector versus illumination wavelength under zero bias in accordance with the concepts of the present invention.

### DETAILED DESCRIPTION OF THE INVENTION

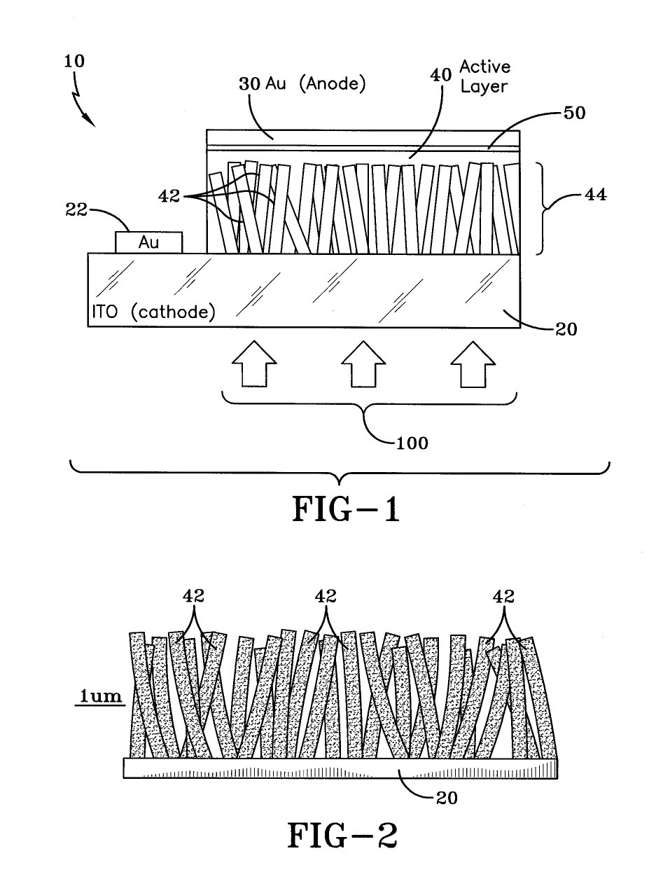

The present invention comprises a photodetector generally referred to by the numeral 10 as shown in FIG. 1 of the drawings. Specifically, the photodetector 10 includes an inverted structure, that includes an at least partially light transparent cathode 20, such as an indium-tin-oxide (ITO) having a gold (Au) contact 22 disposed thereon. The cathode 20 is separated from an anode 30 that is formed of high work-function metal, such as a silver or gold by an active layer 40. Specifically, the active layer 40 is formed of one or more small or narrow bandgap conjugated polymers, such as a mixture or composite of poly(5,7-bis(4-decanyl-2-thienyl)-thieno(3,4-b)diathiazole-thiophene-2,5) (PDDTT) and (6,6)-phenyl-C₆₁-butyric acid methyl ester (PCBM). Thus, the active layer 40 may be formed of a composite of one or more conjugated polymers, as the electron donors, and and one or more organic molecules, such as fullerene, as an electron acceptor. The active layer 40 is disposed upon a cathode buffer layer or nanowire layer 44 formed by a matrix/array/network of a plurality of zinc oxide (ZnO) nanowires 42 that are disposed upon the ITO cathode 20. It should be appreciated that the nanowires 42, in addition to ZnO, may be formed of any other suitable n-type metal oxide, and are configured, so as to be substantially vertically aligned relative to the cathode 20. Finally, an anode buffer layer 50 of MoO₃ (i.e. hole extraction layer) is disposed between the active layer 40 and the high-work-function anode 30 to form the photodetector 10. Thus, during the operation of the photodetector 10, the ZnO nanowire layer 44 (i.e. electron extraction layer) serves to provide a wide bandgap and enhanced surface area, so as to allow the effective extraction of electrons and blocking of holes from the active layer 40 to the electrode underneath.

It should be appreciated that the use of the ZnO nanowire buffer layer 44 (i.e. cathode buffer layer) and the MoO₃ buffer layer 50 (i.e. anode buffer layer) in the structure of the photodetector 10 break the symmetry of the diode formed by the polymer active layer 40 that is disposed between the ITO cathode 20 and the metal anode 30. It should be appreciated that in one aspect, the active layer 40 may be formed so as to be about 200 nm and processed with 3.0% DIO (1,8-diiodooctane) for example. It is also contemplated that the anode and cathode buffer layers 44 and 50 are comprised of organic and/or inorganic semiconductors, and may be water soluble small molecules as well. It should also be appreciated that the active layer 40 is solution processible. Furthermore, it is also contemplated that the active layer 40 may be formed from conjugated polymers, fullerene or fullerene derivatives and inorganic quantum dots.

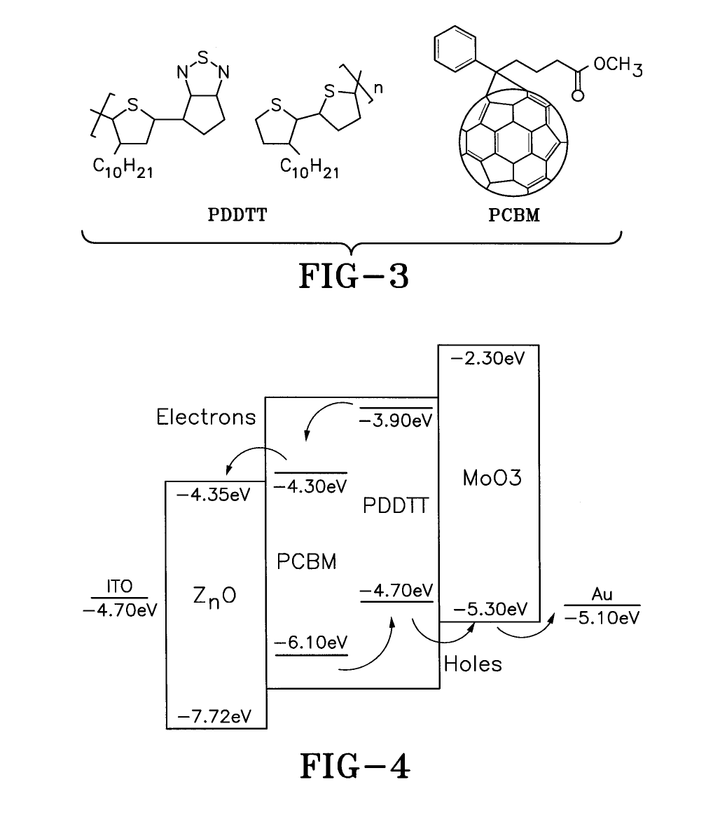

To form the photodetector 10, the nanowire layer 44 is formed by disposing a ZnO seeding layer of approximately 45 nm in thickness onto the ITO glass or cathode layer 20 using low pressure RF (radio frequency) magnetron sputtering on a 99.99% ZnO target for approximately 16 minutes with a chamber pressure of 1.7 mTorr. Solvothermal growth of ZnO nanowires, using 25 mM solutions of zinc acetate and hexamethylenetetramine (HMTA, Sigma) in deionized water (>17.6 MSΩ·cm), was carried out with gentle agitations at 85 degrees C. for 3.5 hrs. The as-growth samples were then rinsed with deionized water and sonicated at 30 W for 1 minute to remove surface residual particles and blow-dried with N₂. Most of the formed ZnO nanowires 42, shown in FIGS. 1 and 2, grow vertically on the ITO glass substrate or cathode layer 20, and have hexagonal cross-sections indicating that their growth is along a c-direction. In one aspect, the nanowires 42 may have an average diameter of about 200 nm and a length of about 2 um for example. In another aspect, the spacing between the zinc (ZnO) nanowires 42 may vary from 50 nm to 150 nm for example.

Next, a solution of PDDTT:PCBM, having the molecular strucuture, as shown in FIG. 3, at a ratio of 1:3 with a concentration of 2 wt % in dichlorobenzene is spin-cast upon the matrix or array of zinc oxide nanowires 42 that extend from the indium-tin-oxide (ITO) cathode layer 20. The PDDTT:PCBM mixture is then dried for 10 minutes at 80 degrees C., thereby forming the active layer 40 that is approximately 150 nm in thickness above the ZnO nanowires 42 of the cathode buffer layer 44. In addition, the PDDTT:PCBM mixture forming the active layer 40 was fully embedded in the spaces or voids between the nanowires 42 of the nanowire layer 44. Next, the thin layer 50 of MoO₃ is thinly disposed upon the top of the active layer 40, so as to be approximately 15 nm thick, and subjected to an evaporation rate of approximately 0.5 Å/s. Finally, the anode 30, formed as a layer of silver or gold, for example, is disposed upon the MoO₃ layer 50 through a shadow mask by thermal evaporation in a vacuum of about 10⁻⁶ Torr. It should be appreciated that the surface area of the active area 40 of the resultant polymer photodetector may be about 0.45 mm².

The ZnO nanowires 42 serve as an n-type buffer layer on top of the ITO cathode 20 due to their significant electronic properties, whereby the ZnO nanowires 42 have an electron concentration of up to 1˜5×10¹⁸ cm⁻³, and an electron mobility of 1˜5 cm²/V·s. Due to this large electron mobility, the ZnO nanowires 42 have enhanced electron transport properties. In addition, the large surface-to-volume ratio and vertical alignment positions the ZnO nanowires 42 in good contact with the polymer PDDTT:PCBM composite of the active layer 44, which allows the nanowires 42 to collect the electrons in a close distance. The deep highest occupied molecular orbital (HOMO) energy level of up to −7.72 eV of the ZnO nanowires 42 prevents holes from being transported to the cathode 20, which greatly reduces the charge carrier recombination. Moreover, the nanowire layer 42 has a high light transmittance in the visible spectral range and high absorption co-efficiency in the UV (ultraviolet) range. It should be appreciated that the blocking/absorbing of UV radiation by the ZnO nanowires 42 from the active polymer layer 40 imparts better stability to the photodetector 10.

The energy band diagram of the inverted photodetector device 10 and the step-like energy level alignments that are achieved, as shown in FIG. 4, reduce the energy barriers that are required for a charge carrier's transport. With the configuration of the photodetector 10 discussed above, the photodetector 10 operates such that incident light 100, as shown in FIG. 1, travels through the ITO glass cathode layer 20 and the ZnO nanowires 42 of the cathode buffer layer 44, whereupon it is shined or incident on the polymer active layer 40. Furthermore, the top gold anode contact 30 also serves as a light reflection mirror, which enhances and increases the efficiency in which light is absorbed by the photodetector 10.

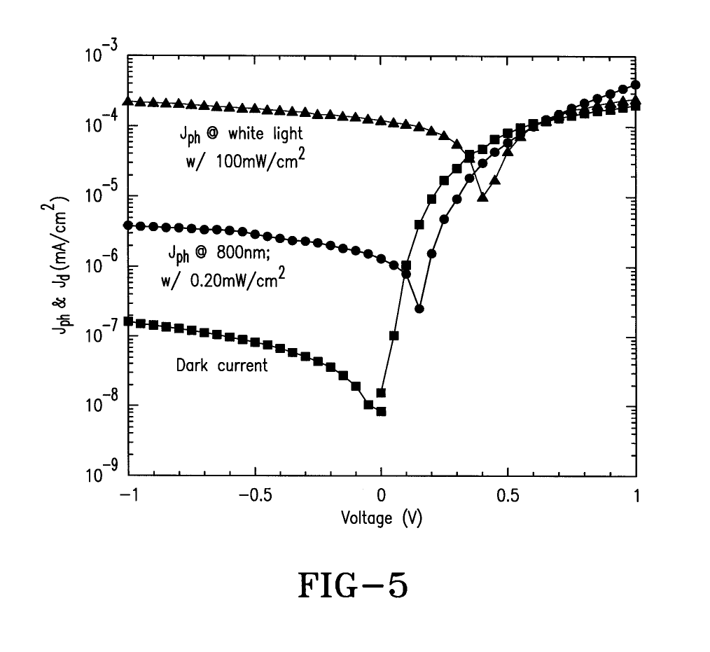

The photodector 10 was evaluated under an illumination of 100 m W/cm² with an AM1.5 solar simulator (Oriel model 91192) and at an illumination of 0.22 mW/cm² at 800 nm. The current density-voltage (J-V) characteristics are shown in FIG. 5. In the dark, the J-V curve shows the behavior of the photodetector 10 when the photodetector 10 is reverse biased and then illuminated by light, whereupon the photogenerated charge carriers greatly increase the reverse current, however, there is not much change in the forward current. The increased electron-hole pairs generated by the photodetector 10 were responsible for the observed photocurrent under reversed bias conditions. Photocurrent response of the photodetector 10 increased from 1.9×10⁻⁷ mA/cm² to 4×10⁻⁶ mA/cm² under an illumination of 800 nm (0.22 mW/cm²) and further to 1.9×10⁻⁴ mA/cm² under AM1.5G solar illumination of 100 mW/cm²). The Jₚₕ (photo current density) and J_{d} (dark current density) ratio is 1000 in this case. Such testing confirmed that the charge carriers can be efficiently generated by photo-induced electron transfer and subsequently transported via the bulk heterojunction (BHJ) nanomorphology to opposite electrodes.

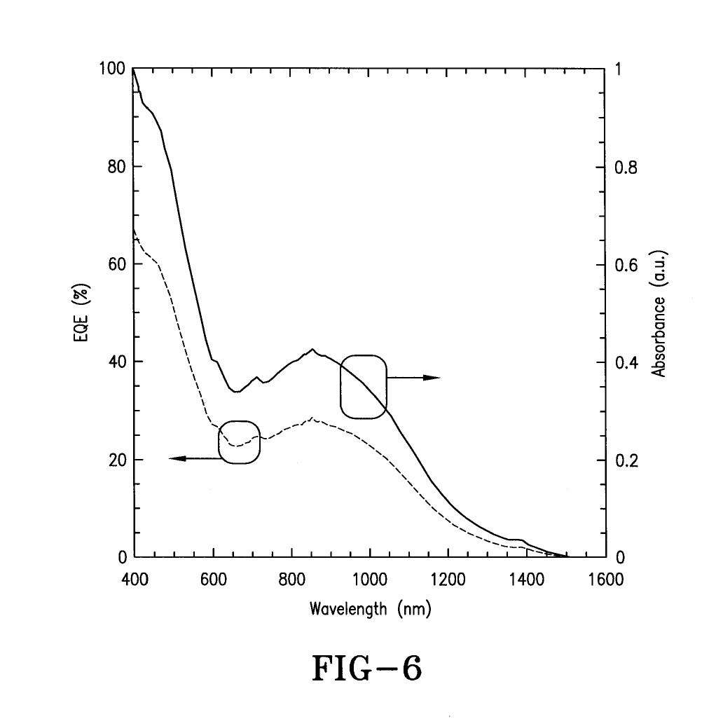

Responsivity of the photodetector 10 was calculated from the measured photoresponse current density, and is expressed by

$${R}_{λ} = \frac{{J}_{ph}}{{P}_{inc}} \qquad ( 1 )$$

where, R_{λ} is the responsivity of the photodetector in A/W, Jₚₕ is the measured current densities from the photodetector 10 in A/cm², and P_{inc} is the incident optical power. The external quantum efficiency (EQE) is given by

$$E Q E = 1240 \cdot {R}_{λ} \frac{q}{hv} \qquad ( 2 )$$

where q, h, and v, are respectively the electron charge in Coulombs, Plank's constant in J-s, and the frequency of the incident photon, whereby λ is the wavelength in nm. Additionally, if the dark current is the major contribution for the noise, the detectivity can be expressed as

$${D}^{*} = \frac{{R}_{λ}}{\sqrt{2 q \cdot {J}_{d}}} \qquad ( 3 )$$

where D* is the detectivity in cm·Hz^{1/2}/W or Jones, and J_{d} is the dark current density of polymer PDs in A/Cm². The measured EQE under short-circuit conditions and the absorption spectrum of the PDDTT:PCBM thin film layer 44 are presented in FIG. 6. The similar profiles of absorption and EQE spectra of the PDDTT:PCBM mixture 44 demonstrate that photons absorbed by PDDTT in the near infrared contributed to the photocurrent. Under zero bias, at λ=800 nm, the Jₚₕ is ˜4×10⁻³ A/cm². According to equations (1) and (2), the R_{λ} and EQE is 0.18 A/W and 27%, respectively.

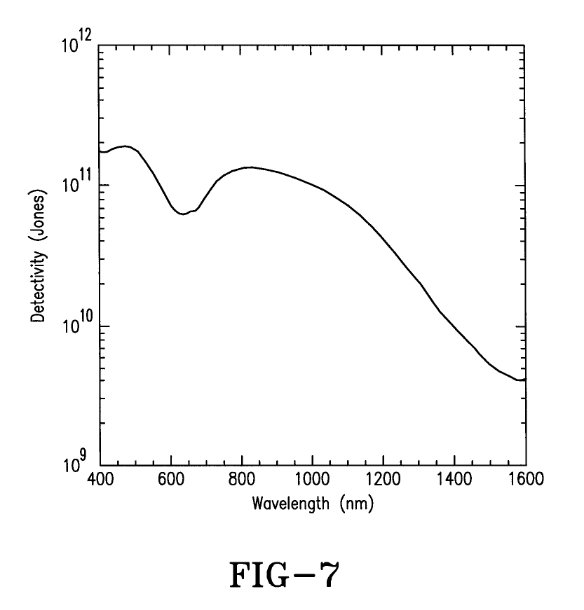

The detectivity of the polymer photodetector 10 having an inverted device structure, as a function of wavelength, is illustrated in FIG. 7. According to equation (3), at zero bias, the detectivity D* of the polymer photodetector at 800 nm and 1400 nm is ˜2×10¹¹ Jones and ˜8×10⁹ Jones, respectively. Operating at room temperature, the polymer photodetector 10 exhibited a spectral response for wavelengths from 400 nm to 1450 nm, wherein a detectivity of greater than 10¹⁰ Jones was attained for wavelengths from 400 nm to 1300 nm, and a detectivity of greater than 10⁹ Jones was attained for wavelengths from 1300 nm to 1450 nm. Thus, the detectivity of the polymer photodetector 10 with an inverted device structure of that of the present invention was comparable to inorganic photodetectors using a conventional non-inverted device structure.

Therefore, one advantage of the present invention is that a high performance broadband photodetector is based on blend or mixture of narrow band conjugated PDDTT and PCBM polymers having an inverted device structure, whereby electrons and holes are collected on ITO and metal contact with high work functions. Still another advantage of the present invention is that a polymer photodetector utilizes a cathode buffer layer having a high quality vertical ZnO nanowire array with a wide bandgap and an enhanced surface area, which allows for the effective extraction of electrons and for the effective blocking of holes from the active BHJ layer to the cathode underneath. Yet another advantage of the present invention is that a polymer photodetector is configured as an inverted device that exhibits a spectral response from UV (ultra-violet) to IR (infrared) wavelengths (approximately 400 nm-1450 nm), with a detectivity of greater than 10¹⁰ Jones for wavelengths from about 400 nm to 1300 nm and greater than 10⁹ Jones for wavelengths from about 1300 nm to 1450 nm. Another advantage of the present invention is that a polymer photodetector uses an inverted structure, which allows its operating life to be extended by minimizing contact oxidation (low work function metal contacts are not needed in this case).

Thus, it can be seen that the objects of the invention have been satisfied by the structure and its method for use presented above. While in accordance with the Patent Statutes, only the best mode and preferred embodiment has been presented and described in detail, it is to be understood that the invention is not limited thereto or thereby. Accordingly, for an appreciation of the true scope and breadth of the invention, reference should be made to the following claims.

What is claimed is:

1. A polymer photodetector having an inverted structure comprising:
an at least partially light transparent cathode;
a metal anode;
a first buffer layer disposed upon said cathode, said first buffer layer including a matrix of ZnO nanowires;
an active layer disposed upon said first buffer layer, said active layer comprising one or more conjugated polymers and a fullerene; and
a second buffer layer disposed between said active layer and said metal anode.

2. The photodetector of claim 1, wherein said cathode comprises indium-tin-oxide (ITO).

3. The photodetector of claim 1, wherein said metal anode comprises a high work-function metal.

4. The photodetector of claim 3, wherein said high work-function metal comprises gold or silver.

5. The photodetector of claim 1, wherein said one or more polymers comprises poly(5,7-bis(4-decanyl-2-thienyl)-thieno(3,4-b)diathiazole-thiophene-2,5) (PDDTT) and said fullerene comprises (6,6)-phenyl-C₆₁-butyric acid methyl ester (PCBM).

6. The photodetector of claim 5, wherein said second buffer layer comprises MoO₃.

7. The photodetector of claim 1, wherein said first buffer layer and said second buffer layer are each inorganic semiconductors.

8. The photodetector of claim 1, wherein said first buffer layer and said second buffer layer are each organic semiconductors.

9. The photodetector of claim 8, wherein said first buffer layer and said second buffer layer are each water-soluble organic semiconductors.

10. The photodetector of claim 9, wherein said first buffer layer and said second buffer layer include water-soluble small molecules and conjugated polymers.

11. The photodetector of claim 1, wherein said active layer includes inorganic quantum dots.

12. A polymer photodetector having an inverted structure comprising:
an at least partially light transparent cathode;
a metal anode;
a first buffer layer disposed upon said cathode, said first buffer layer including a matrix of n-type metal oxide nanowires;
an active layer disposed upon said first buffer layer, said active layer including one or more conjugated polymers as an electron donor, and one or more organic molecules as an electron acceptor; and
a second buffer layer disposed between said active layer and said metal anode, said second buffer layer comprising a metal complex.

13. The photodetector of claim 12, wherein said one or more conjugated polymers comprises poly(5,7-bis(4-decanyl-2-thienyl)-thieno(3,4-b)diathiazole-thiophene-2,5) (PDDTT).

14. The photodetector of claim 12, wherein said organic molecule comprises (6,6)-phenyl-C₆₁-butyric acid methyl ester (PCBM).

15. The photodetector of claim 14, wherein said metal complex comprises MoO₃.

16. The photodetector of claim 12, wherein said organic molecule comprises a fullerene.

17. The photodetector of claim 12, wherein said n-type metal oxide nanowires comprise ZnO nanowires.

18. The photodetector of claim 12, wherein said first buffer layer and said second buffer layer are each inorganic semiconductors.

19. The photodetector of claim 12, wherein said metal anode comprises a high work-function metal.

20. The photodetector of claim 19, wherein said high work-function metal comprises gold or silver.

21. A method of forming a photodetector having an inverted structure comprises:
providing an at least partially light transparent cathode;
disposing a first buffer layer upon said at least partially light transparent cathode, said first buffer layer including a matrix of n-type metal oxide nanowires;
disposing an active layer upon said first buffer layer, said active layer including one or more conjugated polymers as an electron donor, and one or more organic molecules as an electron acceptor;
disposing a second buffer layer upon said active layer, said second buffer layer comprising a metal complex; and
disposing a metal anode upon said second buffer layer.

22. The method of claim 21, wherein said n-type metal oxide nanowires comprises ZnO nanowires.

23. The method of claim 22, wherein said metal complex comprises MoO₃.

24. The method of claim 23, wherein said metal anode comprises a high work-function metal.

25. The photodetector of claim 24, wherein said high work-function metal comprises gold or silver.
